(19) United States
(12) Patent Application Publication
(10) Pub. No.: US 2025/0221175 A1
(43) Pub. Date: Jul. 3, 2025

(54) LIGHT EMITTING DISPLAY DEVICE

(71) Applicant: LG Display Co., Ltd., Seoul (KR)

(72) Inventors: Seok Hyun KIM, Paju-si (KR); Kwan Soo KIM, Paju-si (KR); Jong Woo PARK, Paju-si (KR); Min Jee KIM, Paju-si (KR)

(21) Appl. No.: 19/002,184

(22) Filed: Dec. 26, 2024

(30) Foreign Application Priority Data
Dec. 29, 2023 (KR) 10-2023-0197123

(51) Int. Cl. H10K 59/122; H10K 50/858; H10K 59/124; H10K 102/00

(52) U.S. Cl. CPC H10K 59/122; H10K 50/858; H10K 59/124; H10K 2102/351

(57) ABSTRACT

Disclosed is a light emitting display device and manufacturing method thereof. The light emitting display device includes a light emitting device including a first electrode, an intermediate layer, and a second electrode at each of a plurality of emission areas on a substrate, a first capping layer and a second capping layer sequentially provided on the light emitting device and configured to have different refractive indexes, a first pattern defining layer adjacent to a side surface of the second electrode and provided at each of a plurality of transmission areas on the substrate, and a second pattern defining layer adjacent to a side surface of the second capping layer and configured to overlap the first pattern defining layer.

### CROSS-REFERENCE TO RELATED APPLICATION(S)

This application claims the priority benefit of Korean Patent Application No. 10-2023-0197123, filed on Dec. 29, 2023, the entire contents of which are hereby expressly incorporated for all purposes.

### BACKGROUND

### Technical Field

The present disclosure relates to a light emitting display device, and more particularly, to a light emitting display device and manufacturing method thereof which may improve transmittance of a transmission area.

### Description of the Related Art

As society enters the information age, the field of display devices that visually display electrical information signals is developing rapidly. Accordingly, research to develop performance of various display devices, such as reduction in thickness, weight, and power consumption, is continuing.

Thereamong, a light emitting display device includes light emitting devices which are self-luminous devices, and does not require any separate light source used in non-light-emitting devices, thereby making it possible to reduce weight and thickness.

A display device panel may be provided with a sensor. As the size of the display device panel has recently decreased or developed into a bezel-less structure or a seamless structure, the sensor may be located on the display device panel.

The description provided in the description of the related art section should not be assumed to be prior art merely because it is mentioned in or associated with the description of the related art section. The description of the related art section may include information that describes one or more aspects of the subject technology, and the description in this section does not limit the invention.

### BRIEF SUMMARY

The inventors have recognized that, since light transmittance of the sensor is low, there is a problem in that perceived image quality is deteriorated. Accordingly, the present disclosure is directed to a light emitting display device that substantially obviates one or more technical problems due to limitations and disadvantages of the related art, including the above-identified problem.

Various embodiments of the present disclosure provide a light emitting display device which has a first pattern defining layer adjacent to a second electrode in an area corresponding to a transmission area of a sensor, and a second pattern defining layer adjacent to a second capping layer so as to improve transmittance of the transmission area, and may thus improve overall transmittance of the sensor to improve perceived image quality.

Additional advantages, benefits, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

A light emitting display device of the present disclosure has a first pattern defining layer adjacent to a second electrode in an area corresponding to a transmission area of a sensor, and a second pattern defining layer adjacent to a second capping layer so as to improve transmittance of the transmission area, and may thus improve overall transmittance of the sensor to improve perceived image quality.

To achieve these technical benefits and other advantages and in accordance with the purpose of the disclosure, as embodied and broadly described herein, a light emitting display device includes a light emitting device including a first electrode, an intermediate layer, and a second electrode at each of a plurality of emission areas on a substrate, a first capping layer and a second capping layer sequentially provided on the light emitting device and configured to have different refractive indexes, a first pattern defining layer adjacent to a side surface of the second electrode and provided in each of a plurality of transmission areas on the substrate, and a second pattern defining layer adjacent to a side surface of the second capping layer and configured to overlap the first pattern defining layer.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate exemplary embodiment(s) of the disclosure and together with the description serve to explain the principle of the disclosure. In the drawings:

FIG. 1 is a plan view of a light emitting display device of the present disclosure according to the exemplary embodiment;

FIG. 2 is a schematic cross-sectional view of a light emitting display device of the present disclosure according to a first exemplary embodiment;

FIG. 3 is a schematic plan view of the light emitting display device of the present disclosure according to the first exemplary embodiment;

FIG. 4 is a cross-sectional view of the light emitting display device of the present disclosure according to the first exemplary embodiment;

FIG. 5 is a schematic plan view of a light emitting display device of the present disclosure according to a second exemplary embodiment;

FIG. 6 is a cross-sectional view of the light emitting display device of the present disclosure according to the second exemplary embodiment;

FIG. 7 is a schematic cross-sectional view of a light emitting display device of the present disclosure according to a third exemplary embodiment;

FIG. 8 is a cross-sectional view of the light emitting display device of the present disclosure according to the third exemplary embodiment;

FIG. 9A and FIG. 9B are schematic plan views showing various shapes of the light emitting display device of the present disclosure;

FIG. 10A and FIG. 10B are schematic cross-sectional views showing various shapes of the light emitting display device of the present disclosure;

FIG. 11A, FIG. 11B, FIG. 11C, and FIG. 11D are schematic plan views showing various shapes of the light emitting display device of the present disclosure;

FIG. 12 is a cross-sectional view of a light emitting display device of the present disclosure according to a fourth exemplary embodiment; and

FIG. 13 is a graph showing transmittance of the light emitting display device of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and methods for achieving the same will become apparent from the descriptions of various examples herein below with reference to the accompanying drawings. However, the present disclosure is not limited to the various examples disclosed herein but may be implemented in various different forms. The examples of the present disclosure are provided to make the description of the present disclosure thorough and to fully convey the scope of the present disclosure to those skilled in the art. It is to be noted that the examples of the present disclosure are defined only by the claims.

The shape, size, ratio, angle, number, and the like shown in the drawings to illustrate various exemplary embodiments of the present disclosure are merely provided for illustration, and the disclosure is not limited to the content shown in the drawings. Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure.

When terms such as “include,” “have,” “comprise,” “contain,” “constitute,” “make up of,” “formed of,” and “consist of” are used throughout the disclosure, an additional component may be present, unless “only” is used. A component described in a singular form encompasses a plurality thereof unless particularly stated otherwise.

The shapes, sizes, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The components included in the exemplary embodiments of the present disclosure should be interpreted to include an error range, even if there is no additional particular description thereof.

In describing the variety of exemplary embodiments of the present disclosure, when terms describing positional relationships such as “on”, “above”, “over”, “below”, “under”, “beside”, “beneath”, “near”, “close to,” “adjacent to”, “on a side of”, “next” are used, at least one intervening element may be present between the two elements, unless “immediately” or “directly” is also used.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When an element or layer is disposed “on” another element or layer, another layer or another element may be interposed directly on the other element or therebetween.

In describing the variety of exemplary embodiments of the present disclosure, when terms related to temporal relationships, such as “after”, “subsequently”, “next”, and “before”, are used, the non-continuous case may be included, unless “immediately” or “directly” is also used.

In describing the variety of exemplary embodiments of the present disclosure, terms such as “first”, “second”, “A”, “B”, “(A)”, or “(B)” may be used to describe a variety of components, but these terms only aim to distinguish the same or similar components from one another. Accordingly, throughout the disclosure, a “first” component may be the same as a “second” component within the technical concept of the present disclosure, unless specifically mentioned otherwise.

“First horizontal axis direction”, “second horizontal axis direction”, and “vertical axis direction” should not be interpreted as only geometric relationships in which relationships between these directions are perpendicular, and may have broader directionality within the scope in which components of the present disclosure may work functionally.

The term “at least one” should be understood to include all possible combinations from one or more related items. For example, “at least one of a first item, a second item, or a third item” means each of the first, second, and third items, as well as all combinations of two or more of the first, second, and third items.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Respective features of various examples of the present disclosure may be partially or entirely coupled to or combined with each other, and may be technically variously interconnected or operated, and the respective examples may be implemented independently of each other or implemented together in associative relations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In giving reference numerals to components in the respective drawings, identical components may have the same reference numerals as much as possible even if they are shown in different drawings. In addition, the scale of the components shown in the attached drawings may be different from an actual scale for convenience of explanation, and thus the present disclosure is not limited to the scale shown in the drawings.

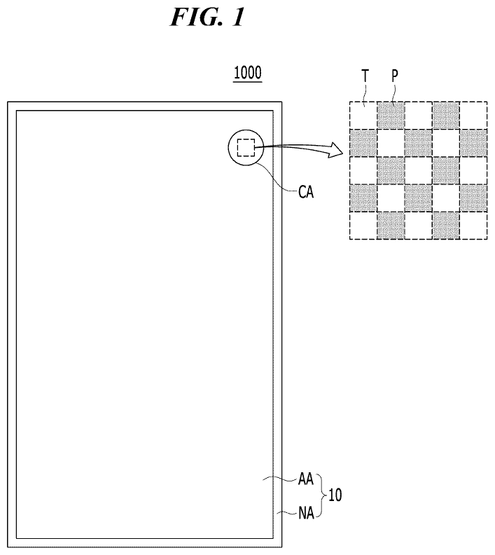

FIG. 1 is a plan view of a light emitting display device 1000 of the present disclosure according to exemplary embodiment.

Referring to FIG. 1, the light emitting display device 1000 of the present disclosure according to exemplary embodiment may include a substrate 10 including an active area AA and a non-active area NA, and a sensor CA which is defined as a designated area may be included in the active area AA. The sensor CA may include a plurality of transmission areas T and a plurality of pixels P.

The substrate 10 may be divided into the active area AA in which a screen appears and the non-active area NA in which the screen does not appear. The non-active area may be an area adjacent to the active area. Further, the non-active area may be an area disposed adjacent to the active area and configured to surround the active area. However, the present disclosure is not limited thereto.

For example, the non-active area may include a first non-display area located outside the active area in a first direction, a second non-display area located outside the active area in a second direction intersecting the first direction, a third non-display area located outside the active area in the opposite direction to the first direction, and a fourth non-display area located outside the active area in the direction opposite to the second direction.

For another example, a boundary area between the active area and the non-active area may be bent so that the non-active area may be located below the display area. In this case, when the user looks at the display device from the front, there may be little or no non-active area visible to the user.

The substrate 10 may be formed as a glass substrate or a flexible plastic substrate. In some exemplary embodiments, the substrate 10 may be made of a flexible polymer film. For example, the flexible polymer film may be made of any one of polyamide, polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. For example, the flexible plastic substrate may include polyimide or polyamide.

The active area AA may include the plurality of pixels P. Particularly, the active area AA may include the sensor CA in a predetermined area. The sensor CA may include the plurality of pixels P and the plurality of transmission areas T. The plurality of pixels P and the plurality of transmission areas T may be alternately arranged in row and column directions, as shown in FIG. 1. However, the arrangement structure of the plurality of pixels P and the plurality of transmission areas T of the present disclosure is not limited thereto. As such, the light emitting display device 1000 of the present disclosure may include the plurality of pixels P and the plurality of transmission areas T in the sensor CA, and may output a full screen image through the plurality of pixels P in the entire active area AA.

The sensor CA may be an area having a low pixel density within the active area AA of the light emitting display device 1000. The sensor CA may receive or transceive various sensing lights, such as infrared rays of external light. For example, the sensor CA may include various sensors, such as a camera, an infrared camera, an infrared sensor, and an illuminance sensor. For this purpose, the light emitting display device 1000 may have the transmission areas T between the plurality of pixels P in order to allow the sensor CA to secure light transmittance of a panel.

The plurality of pixels P may be defined by gate lines and data lines which intersect each other on the substrate 10 to be formed in a matrix. Each of the plurality of subpixels SP is a minimum unit which configures the area and n subpixels SP form one pixel. Each of the plurality of subpixels SP may emit light having different wavelengths from each other. The plurality of subpixels may include first to third subpixels which emit different color light from each other. The plurality of pixels P of the present disclosure may include subpixels which emit red, green, and blue light. However, the plurality of pixels P is not limited thereto, and may further include, for example, a subpixel which emits white light. The plurality of subpixels SP may be variously modified in colors and configurations, as necessary. However, the present disclosure is not limited thereto.

For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

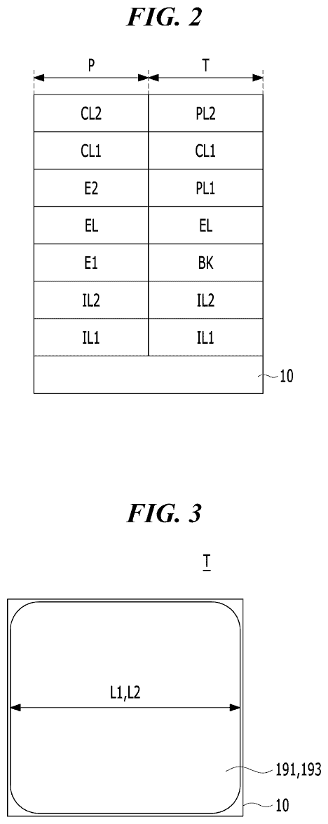

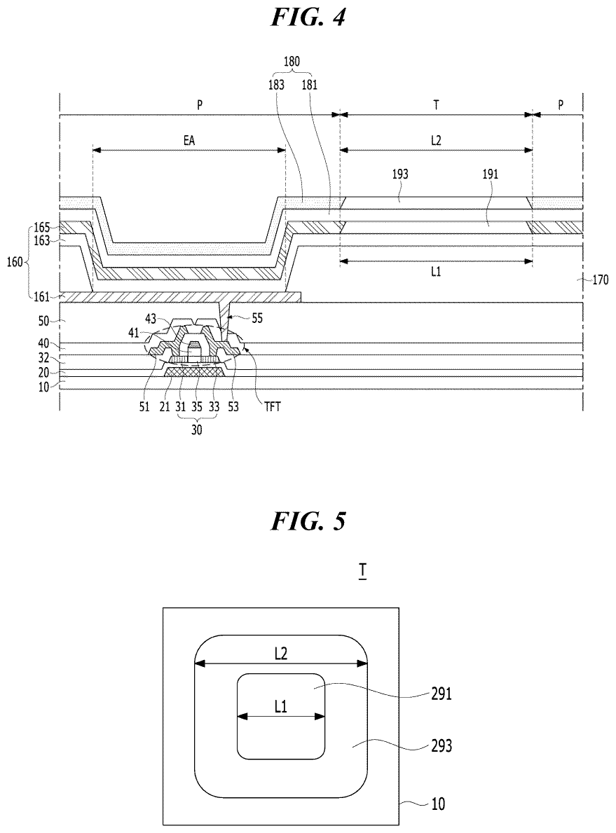

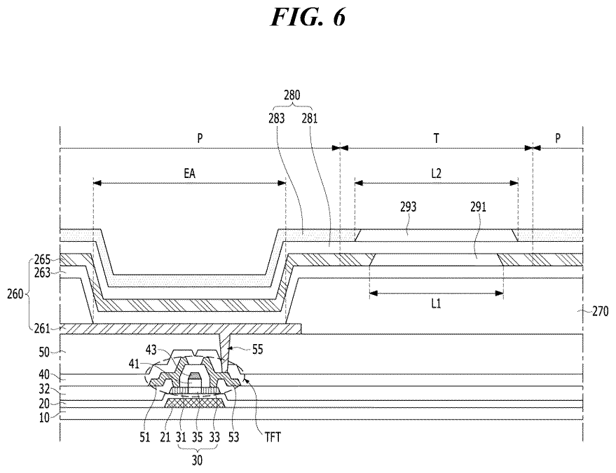

FIG. 2 is a schematic cross-sectional view of a light emitting display device of the present disclosure according to a first exemplary embodiment, and FIG. 3 is a schematic plan view of the light emitting display device of the present disclosure according to the first exemplary embodiment. In addition, FIG. 4 is a cross-sectional view of the light emitting display device of the present disclosure according to the first exemplary embodiment.

Referring to FIG. 2, the light emitting display device of the present disclosure may sequentially include a first insulating layer IL1, a second insulating layer IL2, a first electrode E1, an intermediate layer EL, a second electrode E2, a first capping layer CL1, and a second capping layer CL2 in an area corresponding to the pixel P on the substrate 10, and may sequentially include the first insulating layer IL1, the second insulating layer IL2, a bank BK, the intermediate layer EL, a first pattern defining layer PL1, the first capping layer CL1, and a second pattern defining layer PL2 in an area corresponding to the transmission area T on the substrate 10. Here, the pixel P in FIG. 2 represents an area corresponding to an emission area EA. The light emitting display device of the present disclosure according to the first exemplary embodiment may have the first pattern defining layer PL1 in the transmission area T adjacent to the second electrode E2, and may have the second pattern defining layer PL2 in the transmission area T adjacent to the second capping layer CL2.

Referring to FIG. 3, the first pattern defining layer PL1 and the second pattern defining layer PL2 according to the first exemplary embodiment are formed to have the same area, and may thus have a first width L1 and a second width L2 which are the same, respectively. The first pattern defining layer PL1 and the second pattern defining layer PL2 may be provided on the substrate 10 to cover the entirety of the transmission area T.

Referring to FIG. 4, the light emitting display device of the present disclosure includes a light emitting device 160 including a first electrode 161, an intermediate layer 163, and a second electrode 165 provided in each of a plurality of emission areas EA on the substrate 10, a first capping layer 181 and a second capping layer 183 sequentially provided on the light emitting device 160 and having different refractive indexes, a first pattern defining layer 191 adjacent to the side surface of the second electrode 165 and provided in each of the plurality of transmission areas T, and a second pattern defining layer 193 adjacent to the side surface of the second capping layer 183 and configured to overlap the first pattern defining layer 191.

Further, the light emitting display device of the present disclosure may include a transistor TFT and the light emitting display device 160 including the first electrode 161 connected to the transistor TFT, the intermediate layer 163, and the second electrode 165, in an area corresponding to the emission area EA on the substrate 10.

The transistor may be thin-film transistor TFT. Active layer of thin-film transistors TFT may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

On the substrate 10, various signal wires, such as data lines and gate lines, and circuit elements including transistors, such as switching thin film transistors and driving thin film transistors, and capacitors may be formed in each of subpixels. For convenience of explanation, the present disclosure shows one arbitrary transistor TFT which drives one light emitting device 160.

The transistor TFT includes an active layer 30, a gate electrode 43 overlapping a channel region 35 of the active layer 30 with a gate insulating film 41 interposing therebetween, and a source electrode 51 and a drain electrode 53 connected to both sides of the active layer 30.

The active layer 30 of the transistor TFT has a source region 31 and a drain region 33 on both sides of the channel region 35. Each of the source region 31 and the drain region 33 is formed of a semiconductor material implanted with n-type or p-type impurities. The channel region 35 overlapping the gate electrode 43 may be formed of a semiconductor material into which n-type or p-type impurities are not implanted.

The gate electrode 43 of the transistor TFT is provided to have the same width as the channel region 35 of the active layer 30 to overlap the channel region 35 with the gate insulating film 41 interposed therebetween. The gate insulating film 41 is formed in the same pattern as the gate electrode 43 to overlap the channel region 35 of the active layer 30. For example, the gate electrode 43 may be formed in a single layer or a multilayer structure formed of any one of molybdenum (Mo), aluminum (Al), chromium (Cr), gold (Au), titanium (Ti), nickel (Ni), neodymium (Nd), and copper (Cu), or an alloy thereof. Meanwhile, the gate insulating film 41 may be formed of an inorganic insulating material, for example, a silicon oxide (SiOₓ) film, a silicon nitride (SiNₓ) film, a silicon oxynitride (SiOₓN_{y}), or a multilayer film thereof. For example, the gate insulating film 41 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

A light shielding layer 21 on the substrate 10 overlaps at least the channel region 35 of the active layer 30, and is disposed below the active layer 30. The light shielding layer 21 prevents external light from penetrating the substrate 10 and being transmitted to the transistor TFT. For example, the light shielding layer 21 may be formed as a single layer of a metal material, for example, one of molybdenum (Mo), titanium (Ti), aluminum-neodymium (AlNd), aluminum (Al), chromium (Cr), and alloys thereof, or a multilayer structure using the same.

A buffer film 20 on the light shielding layer 21 is provided to cover the light shielding layer 21. For example, the buffer film 20 may be formed as a single layer or multilayer structure using silicon oxide (SiOₓ) and/or silicon nitride (SiNₓ). For example, the buffer film 20 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

An interlayer insulating film 32 on the buffer film 20 may include a source contact hole and a drain contact hole which expose the source region 31 and the drain region 33 of the active layer 30, respectively, and may be provided to cover the gate insulating film 41 and the gate electrode 43. For example, the interlayer insulating film 32 may be formed as a single layer or a multilayer structure formed of a silicon oxide (SiOₓ) film, a silicon nitride (SiNₓ) film, and/or a silicon oxynitride film (SiOₓN_{y}). For example, the interlayer insulating film 32 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The source electrode 51 and the drain electrode 53 may be provided in the same layer on the interlayer insulating film 32. The source electrode 51 and the drain electrode 53 are connected to the source region 31 and the drain region 33 of the active layer 30 through the source contact hole and the drain contact hole, respectively. For example, the source electrode 51 and the drain electrode 53 may be formed as a single layer of a metal material, such as molybdenum (Mo), aluminum (Al), chromium (Cr), gold (Au), titanium (Ti), nickel (Ni), neodymium (Nd), copper (Cu), or an alloy thereof, or may be formed in a multilayer structure using the same.

A first insulating layer 40 on the interlayer insulating film 32 may be provided to cover the transistor TFT. Accordingly, the transistor TFT may be protected by the first insulating layer 40. For example, the first insulating layer 40 is a type of inorganic insulating film, for example, a single layer of one of a silicon oxide (SiOₓ) film, a silicon nitride (SiNₓ) film, a silicon oxynitride (SiOₓN_{y}) film, or a multilayer structure thereof. For example, the first insulating layer 40 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

A second insulating layer 50 may be provided on the first insulating layer 40. The second insulating layer 50 may be formed to have a thickness sufficient to flatten surface steps on the transistor TFT, and may be formed as an organic insulating film. In some cases, if the second insulating layer 50 also functions to protect the transistor TFT, the first insulating layer 40 may be omitted. For example, the first insulating layer 50 may be a type of organic insulating film, and may be formed of one of photo acryl, polyamide, a benzocyclobutene resin, and acrylate, or in some cases, may be formed as a multilayer structure.

The light emitting device 160 including a stacked structure of the first electrode 161, the intermediate layer 163, and the second electrode 165 may be provided on the second insulating layer 50. When current supplied from a power voltage line flows to the second electrode 165 and high-voltage current is supplied from the transistor TFT to the first electrode 161, an electric field is formed between the first electrode 161 and the second electrode 165, the intermediate layer 163 emits light, and thereby, the light emitting device 160 may be driven. Here, the emission area EA where the light emitting device 160 emits light may be an area exposed from a bank 170.

The first electrode 161 may be provided in each of subpixels SP1, SP2, and SP3, and may be electrically connected to each transistor TFT. The first electrode 161 may be formed in a multilayer structure including a transparent conductive film and an opaque conductive film having high reflection efficiency. The transparent conductive film of the first electrode 161 may be formed of a material having a relatively high work function value, such as indium tin oxide (ITO) or indium zinc oxide (IZO), and the opaque conductive film may be formed in a single layer or multilayer structure including at least one selected from the group consisting of silver (Ag), aluminum (Al), copper (Cu), molybdenum (Mo), titanium (Ti), nickel (Ni), chromium (Cr), tungsten (W), and alloys thereof. For example, the first electrode 161 may be formed in a structure in which a transparent conductive film, an opaque conductive film, and a transparent conductive film are sequentially stacked, or in a structure in which a transparent conductive film and an opaque conductive film are sequentially stacked.

The bank 170 may be provided on the entirety of the second insulating layer 50 while exposing the emission area EA. At this time, the bank 170 may be provided to cover the edge of the first electrode 161. For example, the bank 170 may be formed of an organic material, such as polyimide, acrylate, or a benzocyclobutene resin. The bank 170 may be disposed at a boundary between the plurality of subpixels SP and suppress a color mixture of light beams from the plurality of subpixels SP. For example, the bank 170 can be provided between the first electrodes 161 respectively provided in the plurality of subpixels SP1, SP2, and SP3. For example, the bank 170 can be formed to cover an edge of each of the first electrodes 161 and expose a portion of each of the first electrodes 161. Therefore, the bank 170 can prevent a problem in which the light emission efficiency is deteriorated due to the concentration of current at the ends of the first electrodes 161.

The intermediate layer 163 may be provided on the first electrode 161, which is exposed from the bank 170, and the bank 170. The intermediate layer 163 may mean an organic layer of a single stack including multiple layers including a hole injection layer HIL, a hole transport layer HTL, an emission layer EML1 or EML2, an electron transport layer ETL, and an electron injection layer EIL. In the present disclosure, the intermediate layer 163 may indicate a light emitting unit having a tandem structure including a plurality of stacks, for example, a first stack and a second stack having first and second emission layers EML1 and EML2, respectively and a charge generation layer (CGL) between the stacks. Further, the tandem structure is not limited to the two-stack structure, and may include a plurality of stacks, for example, three or more stacks. In the plurality of stacks, the first and second emission layers EML1 and EML2 may be emission layers which emit light of the same color, for example, any one of red, green, and blue light, and may be partially provided in each of the plurality of pixels P. Other layers included in the intermediate layer 163 excluding the first and second emission layers EML1 and EML 2 may be provided over the entire surface of the substrate 10 through common masks. Alternatively, when emitting white light through the first and second emission layers EML1 and EML2 in the two-stack structure or emission layers in a multiple stack structure including three or more stacks, each of the emission layers may be provided over the entire surface of the substrate 10 through a common mask in the same manner as the other layers included in the intermediate layer 163. In addition, the charge generation layer CGL may be formed in a double layer structure including an n-type layer and a p-type layer.

The second electrode 165 may be provided on the intermediate layer 163. The second electrode 165 may be provided adjacent to the first pattern defining layer 191 in the transmission area T. That is, the second electrode 165 may not be provided in the transmission area T. For example, the second electrode 165 may be formed of a transparent conductive material, such as indium tin oxide (ITO) or indium zinc oxide (IZO), or may be formed of silver (Ag), aluminum (Al), magnesium (Mg), calcium (Ca), or an alloy thereof with a thickness small enough to transmit light.

The first pattern defining layer 191 adjacent to the second electrode 165 may be provided on the intermediate layer 163 in an area corresponding to the transmission area T. The first pattern defining layer 191 may be provided throughout the entirety of the transmission area T, and may have a first width L1. Further, the first pattern defining layer 191 may have a lower refractive index than the second electrode 165. Specifically, the first pattern defining layer 191 may have a refractive index of 1.25 to 1.40. For example, the first pattern defining layer 191 may have a refractive index of 1.3 to 1.35, however, the present disclosure is not limited thereto.

The first pattern defining layer 191 has low affinity for conductive materials, and may have a surface on which deposition of the second electrode 165 formed of conductive materials is suppressed. The conductive materials may not be adhered to the surface of the first pattern defining layer 191 due to low affinity for a material forming the first pattern defining layer 191. In other words, the conductive materials forming the second electrode 165 may have a very low surface adhesion probability to the first pattern defining layer 191. Here, the surface adhesion probability may be measured by depositing the amount of a conductive material required to form a closed-pack layer with an average thickness of 1 nm on the surface of the first pattern defining layer 191 in the case of depositing the conductive material. Specifically, the surface adhesion probability of the conductive material to the first pattern defining layer 191 may be deduced by simultaneously depositing the conductive material on the surface of the first pattern defining layer 191 and the substrate 10, and comparing the average thickness of the layer of the conductive material on the surface of the first pattern defining layer 191 to the average thickness of the layer of the conductive material deposited on the substrate 10, when the average thickness of a dense layer of the conductive material on the surface of the first pattern defining layer 191 reaches 1 nm. The surface adhesion probability of the conductive material to the first pattern defining layer 191 may be at most 0.3 (or 30%) and at least 0.0008 (0.08%). For example, the surface adhesion probability of the conductive material to the first pattern defining layer 191 may be 5% to 20%, however, the present disclosure is not limited thereto. Accordingly, during nucleation and growth processes, conductive materials may be desorbed or evaporated or flow to another surface to be fixed to the other surface due to low affinity for the first pattern defining layer 191.

For example, the first pattern defining layer 191 may include a polycyclic aromatic compound including an organic molecule including at least one of heteroatoms, such as nitrogen (N), sulfur (S), oxygen (O), phosphorus (P), and aluminum (Al), as organic materials including organic matter and organic polymers. The polycyclic aromatic compound may include the organic molecule including a core moiety and at least one terminal moiety bonded to the core moiety. For example, the first pattern defining layer 191 may include 3-(4-biphenyl)-4-phenyl-5-tert-butylphenyl-1,2,4-triazole (TAZ), aluminum (III) bis(2-methyl-8-quninolinato)-4-phenylphenolate (BAlq), 2-(4-(9,10-di(naphthalen-2-yl)anthracene-2-yl)phenyl)-1-phenyl-1H-benzo-[D]imidazole, 8-hydroxyquinoline lithium (Liq), N(diphenyl-4-yl)9,9-dimethyl-N-(4(9-phenyl-9H-carbazole-3-yl)phenyl)-9H-fluoren-2-amine, or the like.

Accordingly, the light emitting display device of the present disclosure has the first pattern defining layer 191 formed of organic materials in the transmission area T, and thereby, transmittance of the transmission area T may be improved compared to the case in which the second electrode 165 is provided in the transmission area T. Further, the light emitting display device of the present disclosure does not use a simple organic material in the transmission area T but has the first pattern defining layer 191 with low affinity for the conductive materials forming the second electrode 165, and thereby, a separate mask to form the second electrode 165 after forming the first pattern defining layer 191 may not be required.

A capping layer structure 180 may be provided on the second electrode 165 and the first pattern defining layer 191. The capping layer structure 180 may include at least two layers, for example, a first capping layer 181 and a second capping layer 183. The first capping layer 181 and the second capping layer 183 may include different materials. Further, the first capping layer 181 and the second capping layer 183 may be formed to have different thicknesses. Particularly, the first capping layer 181 and the second capping layer 183 may have different refractive indexes. The capping layer structure 180 may prevent deterioration of the light emitting device 160 due to external moisture or oxygen, and may improve luminous efficacy of the light emitting device 160. The capping layer structure 180 of the present disclosure is not limited thereto, and may further include one or more capping layers on the second capping layer 183.

The first capping layer 181 may be provided on the second electrode 165 and the first pattern defining layer 191 throughout the entire surface of the substrate 10. The first capping layer 181 may be an organic capping layer including organic matter, or a composite capping layer including organic matter and inorganic matter. For example, the first capping layer 181 may include a carbocyclic compound, a heterocyclic compound, an amine group-containing compound, a porphine derivative, a phthalocyanine derivative, a naphthalocyanine derivative, an alkali metal complex, an alkaline earth metal complex, or an arbitrary combination thereof. The carbocyclic compound, the heterocyclic compound, and the amine group-containing compound may be selectively substituted with a substituent including O, N, S, Se, Si, F, Cl, Br, I, or an arbitrary combination thereof.

The second capping layer 183 may be provided on the first capping layer 181. The second capping layer 183 may be formed to have a smaller thickness than the first capping layer 181. However, the present disclosure is not limited thereto, second capping layer 183 may be not formed to have a smaller thickness than the first capping layer 181. Further, the refractive index of the second capping layer 183 may be higher than the refractive index of the first capping layer 181. Accordingly, the light emitting display device of the present disclosure reflects and transmits light from the light emitting device 160 at the interface between the first capping layer 181 and the second capping layer 183, thereby being capable of improving efficiency for emission of light from the light emitting device 160 to the outside. Such a second capping layer 183 may include an inorganic material having low reflectivity, and may include a metal, a metal oxide, or a metal fluoride, but not limited thereto. For example, if the second capping layer 183 includes a metal, the second capping layer 183 may include any one of a ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. If the second capping layer 183 includes a metal oxide or a metal fluoride, the second capping layer 183 may include any one of SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, CdS, or a combination thereof.

The second pattern defining layer 193 adjacent to the second capping layer 183 may be provided on the first capping layer 181 in the area corresponding to the transmission area T. That is, the second capping layer 183 may not be provided in the transmission area T. The second pattern defining layer 193 may be provided throughout the entirety of the transmission area T, and may have a second width L2 which is the same as the first width L1. Accordingly, the second pattern defining layer 193 may be formed to have the same area as the first pattern defining layer 191, and may overlap the first pattern defining layer 191. Further, the second pattern defining layer 193 may have a lower refractive index than the second capping layer 183, and may have a refractive index that is equal to or higher than the first pattern defining layer 191. Specifically, the second pattern defining layer 193 may have a refractive index of 1.25 to 1.45. For example, the second pattern defining layer 193 may have a refractive index of 1.3 to 1.4, but not limited thereto.

The second pattern defining layer 193 may be formed of one selected from the same material group as the first pattern defining layer 191. Alternatively, the second pattern defining layer 193 may include the same material as the first pattern defining layer 191. However, the present disclosure is not limited thereto, and the first pattern defining layer 191 and the second pattern defining layer 193 may include different materials. In addition, since the first pattern defining layer 191 and the second pattern defining layer 193 have different affinities for different components or the first pattern defining layer 191 and the second pattern defining layer 193 have different affinities for same components, the first pattern defining layer 191 and the second pattern defining layer 193 may have different adhesion probabilities to conductive materials.

The second pattern defining layer 193 may include a polycyclic aromatic compound including an organic molecule including at least one of heteroatoms, such as nitrogen (N), sulfur (S), oxygen (O), phosphorus (P), and aluminum (Al), as organic materials including organic matter and organic polymers. The polycyclic aromatic compound may include the organic molecule including a core moiety and at least one terminal moiety bonded to the core moiety. For example, the second pattern defining layer 193 may include 3-(4-biphenyl)-4-phenyl-5-tert-butylphenyl-1,2,4-triazole (TAZ), aluminum (III) bis(2-methyl-8-quninolinato)-4-phenylphenolate (BAlq), 2-(4-(9,10-di(naphthalen-2-yl)anthracene-2-yl)phenyl)-1-phenyl-1H-benzo-[D]imidazole, 8-hydroxyquinoline lithium (Liq), N(diphenyl-4-yl)9,9-dimethyl-N-(4(9-phenyl-9H-carbazole-3-yl)phenyl)-9H-fluoren-2-amine, or the like.

Accordingly, the light emitting display device of the present disclosure has the second pattern defining layer 193 formed of organic materials in the transmission area T, and thereby, transmittance of the transmission area T may be improved compared to the case in which the second capping layer 183 is provided in the transmission area T. Further, the light emitting display device of the present disclosure does not use a simple organic material in the transmission area T but has the second pattern defining layer 193 with low affinity for the conductive inorganic materials forming the second capping layer 183, and thereby, a separate mask to form the second capping layer 183 after forming the second pattern defining layer 193 may not be required.

That is, the light emitting display device of the present disclosure is provided with the first pattern defining layer 191 on the same line as the second electrode 165 instead of the second electrode 165 and the second pattern defining layer 193 on the same line as the second capping layer 183 instead of the second capping layer 183 throughout the transmission area T (for example, the first pattern defining layer 191 is provided in the entire of the transmission area T and the second electrode 165 is provided in other area excluding the transmission area T on the same line, and the second pattern defining layer 193 is provided in the entire of the transmission area T and the second capping layer 183 is provided in other area excluding the transmission area T on the same line, for example, the first pattern defining layer 191 and the second pattern defining layer 193 are disposed to overlap with each other in the entire of the transmission area T, and the second electrode 165 and the second capping layer 183 are disposed to overlap with each other in other area excluding the transmission area T), and thereby, transmittance of the transmission area T may be improved compared to the conventional case in which the second electrode and the second capping layer are provided in the transmission area T.

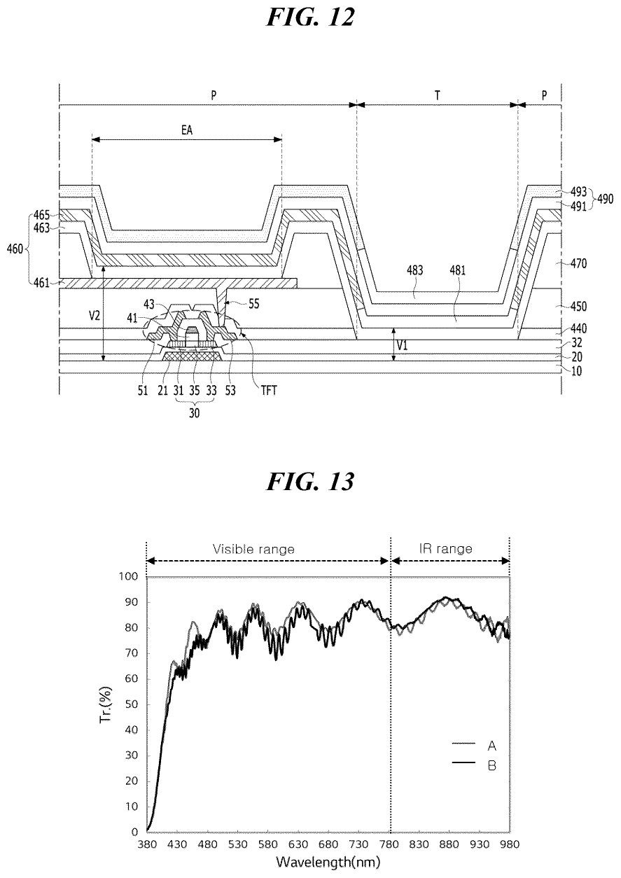

FIG. 13 is a graph which compares transmittance of the transmission area T in which the second pattern defining layer 193 is provided and transmittance of the transmission area T when the second capping layer 183 is provided. In the graph, the horizontal axis represents a wavelength (nm), the vertical axis represents transmittance (%), A indicates the case in which both the first pattern defining layer 191 and the second pattern defining layer 193 are provided in the transmission area T, and B indicates the case in which only the first pattern defining layer 191 is provided in the transmission area T and the first and second capping layers 181 and 183 are provided on the first pattern defining layer 191. Referring to FIG. 13, it can be seen that A has a higher transmittance than B in the visible range of 380 nm to 780 nm. As such, the light emitting display device of the present disclosure has the first and second pattern defining layers 191 and 193 in an overlapping manner in the transmission area T, and may thus improve transmittance. Accordingly, the light emitting display device of the present disclosure improves transmittance of the transmission area T, and may thus improve the overall transmittance of the sensor, thereby being capable of improving perceived image quality.

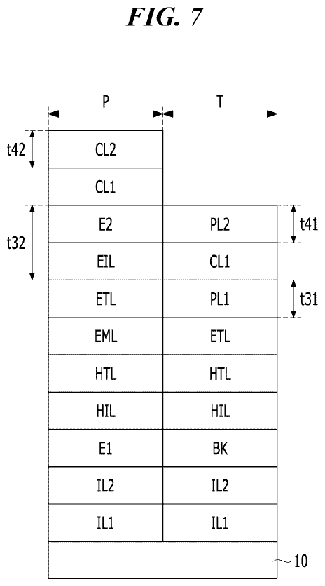

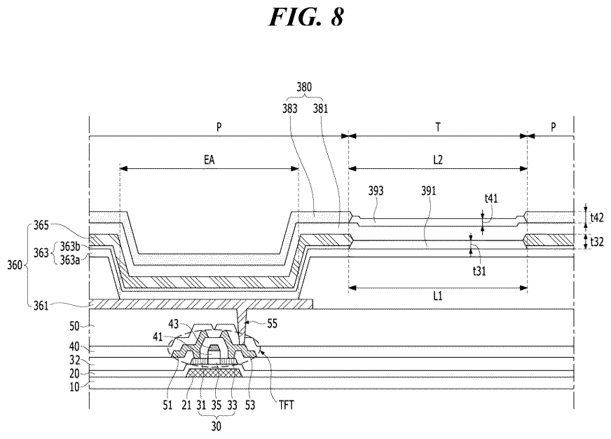

FIG. 5 is a schematic plan view of a light emitting display device of the present disclosure according to a second exemplary embodiment, and FIG. 6 is a cross-sectional view of the light emitting display device of the present disclosure according to the second exemplary embodiment. Hereinafter, a description of the same components as those of the previous exemplary embodiment will be omitted.

Referring to FIG. 5, in the light emitting display device of the present disclosure according to the second exemplary embodiment, a first pattern defining layer 291 and a second pattern defining layer 293 may be formed to have different areas in a transmission area T. Specifically, the first pattern defining layer 291 may be provided in a portion of the transmission area T to have an area having a first width L1, and the second pattern defining layer 293 may be provided in a portion of the transmission area T to have an area having a greater second width L2 than the first width L1.

Referring to FIG. 6, the light emitting display device of the present disclosure may include a light emitting device 260 including a first electrode 261, an intermediate layer 263, and a second electrode 265 provided in each of a plurality of emission areas EA on a substrate 10, a first capping layer 281 and a second capping layer 283 sequentially provided on the light emitting device 260 and having different refractive indexes, the first pattern defining layer 291 adjacent to the side surface of the second electrode 265 and provided in each of the plurality of transmission areas T, and the second pattern defining layer 293 adjacent to the side surface of the second capping layer 283 and configured to overlap the first pattern defining layer 291. Further, the second pattern defining layer 293 according to the second exemplary embodiment has a greater width than the first pattern defining layer 291, and the first pattern defining layer 291 may overlap the inner part of the second pattern defining layer 293. Accordingly, in the present disclosure according to the second exemplary embodiment, the first pattern defining layer 291 having a smaller area overlaps the inner part of the second pattern defining layer 293 having a greater area (for example, an area of the second pattern defining layer 293 is greater than an area of the first pattern defining layer 291, and the first pattern defining layer 291 overlaps with a center portion of the second pattern defining layer 293), and thereby, transmittance of an area in which the first pattern defining layer 291 and the second pattern defining layer 293 overlap each other and transmittance of an area in which the first pattern defining layer 291 and the second pattern defining layer 293 do not overlap each other in the transmission area T may be different. For example, transmittance of an area in which the first pattern defining layer 291 and the second pattern defining layer 293 overlap each other is greater than transmittance of an area in which the first pattern defining layer 291 and the second pattern defining layer 293 do not overlap each other in the transmission area T may be different.

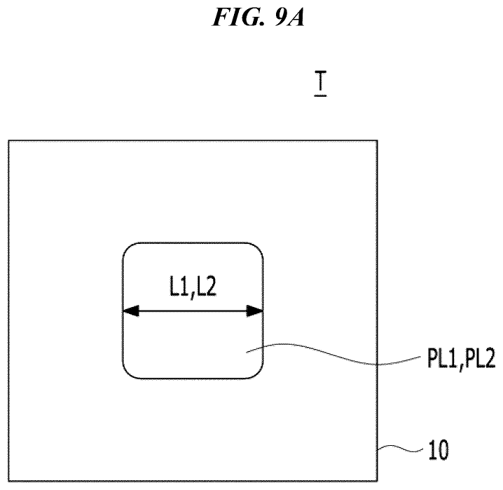

In the light emitting display device of the present disclosure according to the second exemplary embodiment, the first and second pattern defining layers 291 and 293 may not be provided in the entirety of the transmission area T. Further, as the first pattern defining layer 291 and the second pattern defining layer 293 are farther away from the substrate 10 in the transmission area T, the first pattern defining layer 291 and the second pattern defining layer 293 may have gradually larger areas. As such, the exemplary embodiment in which the first pattern defining layer 291 and the second pattern defining layer 293 have different areas may be applied to an exemplary embodiment in which first and second insulating layers IL1 and IL2 and a bank (as BK shown in FIG. 7 and 270 shown in FIG. 6) are selectively removed, which will be described below.

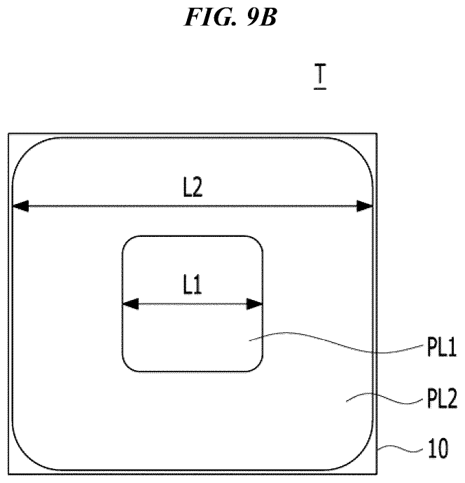

FIG. 7 is a schematic cross-sectional view of a light emitting display device of the present disclosure according to a third exemplary embodiment, and FIG. 8 is a cross-sectional view of the light emitting display device of the present disclosure according to the third exemplary embodiment.

Referring to FIG. 7, the light emitting display device of the present disclosure may sequentially include the first insulating layer IL1, the second insulating layer IL2, a first electrode E1, an intermediate layer HIL, HTL, EML, ETL, and EIL, a second electrode E2, a first capping layer CL1, and a second capping layer CL2 in an area corresponding to a pixel P on a substrate 10, and may sequentially include the first insulating layer IL1, the second insulating layer IL2, the bank BK, the intermediate layer EL, a first pattern defining layer PL1, the first capping layer CL1, and a second pattern defining layer PL2 in an area corresponding to a transmission area T on the substrate 10. Here, the intermediate layer HIL, HTL, EML, ETL, and EIL may include a hole injection layer HIL, a hole transport layer HTL, an emission layer EML, an electron transport layer ETL, and an electron injection layer EIL. However, although the intermediate layer HIL, HTL, EML, ETL, and EIL is shown as a single stack, the present disclosure is not limited thereto and the intermediate layer HIL, HTL, EML, ETL, and EIL may be formed in a plural stack tandem structure having a charge generation layer between stacks.

The light emitting display device of the present disclosure according to the third exemplary embodiment may be provided with the first pattern defining layer PL1 adjacent to the second electrode E2 in the transmission area T and the second pattern defining layer PL2 adjacent to the second capping layer CL2 in the transmission area T. Further, a first thickness t31 of the first pattern defining layer PL1 according to the third exemplary embodiment may be smaller than a second thickness t32, which is the total thickness of the electron injection layer EIL and the second electrode E2, and a first thickness t41 of the second pattern defining layer PL2 may be smaller than a second thickness t42 of the second capping layer CL2.

Referring to FIG. 8, the light emitting display device of the present disclosure may include a light emitting device 360 including a first electrode 361, an intermediate layer 363, and a second electrode 365 provided in each of a plurality of emission areas EA on the substrate 10, a first capping layer 381 and a second capping layer 382 sequentially provided on the light emitting device 360 and having different refractive indexes, a first pattern defining layer 391 adjacent to the side surface of the second electrode 365 and provided in each of a plurality of transmission areas T on the substrate 10, and a second pattern defining layer 393 adjacent to the side surface of the second capping layer 382 and configured to overlap the first pattern defining layer 391. Further, the first and second pattern defining layers 391 and 393 according to the third exemplary embodiment may be formed to have a first width L1 and a second width L2 which are the same, respectively, and may be provided throughout the entirety of the transmission area T. However, the present disclosure is not limited thereto, at least one of the first and second pattern defining layers 391 and 393 may be formed to be partially disposed in the transmission area T.

The intermediate layer 363 provided between the first electrode 361 and the second electrode 365 may include a plurality of common layers. The intermediate layer 363 may include an electron injection layer 363b (or EIL) in contact with the second electrode 365. In addition, the intermediate layer 363 may include a hole injection layer HIL, a hole transport layer HTL, an emission layer EML, and an electron transport layer ETL, as a plurality of common layers 363a which is not in contact with the second electrode 365. Here, the emission layer EML may not be provided as a common layer provided throughout the entirety of the substrate 10, and may be provided for each pixel P.

The first pattern defining layer 391 according to the third exemplary embodiment may be provided adjacent to the side surfaces of the electron injection layer 363b and the second electrode 365. The first pattern defining layer 391 may have low affinity for the electron injection layer 363b. Here, the electron injection layer 363b may include an alkali metal having a low work function, such as Li, Ca, or Mg, a metal ion form, such as LiF or CsF, or a compound, such as Cs₂Co₃ or RbCO₃, but not limited thereto. Accordingly, the first pattern defining layer 391 formed of a polycyclic aromatic compound may have low affinity for the electron injection layer 363b. Therefore, the electron injection layer 363b may be formed in an area excluding the transmission area T through the first pattern defining layer 391. Accordingly, the light emitting display device of the present disclosure may further improve transmittance of the transmission area T.

Further, the first pattern defining layer 391 may be formed to have the first thickness t31 that is smaller than the second thickness t32, which is the total thickness of the electron injection layer 363b and the second electrode 365. That is, the first thickness t31 of the first pattern defining layer PL1 may be smaller than the total thickness of components patterned from the first pattern defining layer 391. Accordingly, the light emitting display device of the present disclosure may further improve transmittance of the transmission area T.

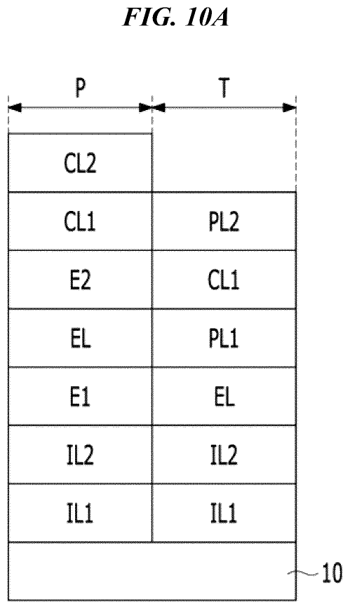

FIG. 9A and FIG. 9B are schematic plan views showing various shapes of the light emitting display device of the present disclosure.

Referring to FIG. 9A, the first pattern defining layer PL1 and the second pattern defining layer PL2 may be formed to have a first width L1 and a second width L2, which are the same, respectively, and the same area so as to overlap each other on the substrate 10. Further, the first pattern defining layer PL1 and the second pattern defining layer PL2 may be provided in a portion of the transmission area T.

Referring to FIG. 9B, the first pattern defining layer PLI and the second pattern defining layer PL2 may be formed to have a first width L1 and second width L2, which are different, respectively and different areas so as to overlap each other on the substrate 10. Further, the second pattern defining layer PL2 may be provided throughout the entirety of the transmission area T, and the first pattern defining layer PL1 may be provided in a portion of the transmission area T.

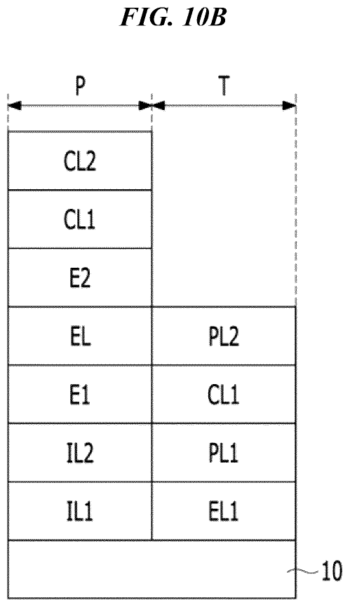

FIG. 10A and FIG. 10B are schematic cross-sectional views showing various shapes of the light emitting display device of the present disclosure.

Referring to FIG. 10A, the light emitting display device may include the first insulating layer IL1, the second insulating layer IL2, the first electrode E1, the intermediate layer EL, the second electrode E2, the first capping layer CL1, and the second capping layer CL2 in an area corresponding to the pixel P on the substrate 10, and may include the first insulating layer IL1, the second insulating layer IL2, the intermediate layer EL, the first pattern defining layer PL1, the first capping layer CL1, and the second pattern defining layer PL2 in an area corresponding to the transmission area T on the substrate 10. That is, in order to maximize the transmittance of the light emitting display device of the present disclosure, the bank may be removed from the area corresponding to the transmission area T.

Referring to FIG. 10B, the light emitting display device may include the first insulating layer IL1, the second insulating layer IL2, the first electrode E1, the intermediate layer EL, the second electrode E2, the first capping layer CL1, and the second capping layer CL2 in an area corresponding to the pixel P on the substrate 10, and may include the intermediate layer EL, the first pattern defining layer PL1, the first capping layer CL1, and the second pattern defining layer PL2 in an area corresponding to the transmission area T on the substrate 10. That is, in order to maximize the transmittance of the light emitting display device of the present disclosure, the first insulating layer, the second insulating layer, and the bank may be removed from the area corresponding to the transmission area T.

As described above, it is possible to maximize the transmittance of the light emitting display device of the present disclosure, by removing the first insulating layer, the second insulating layer, and/or the bank from the area corresponding to the transmission area T

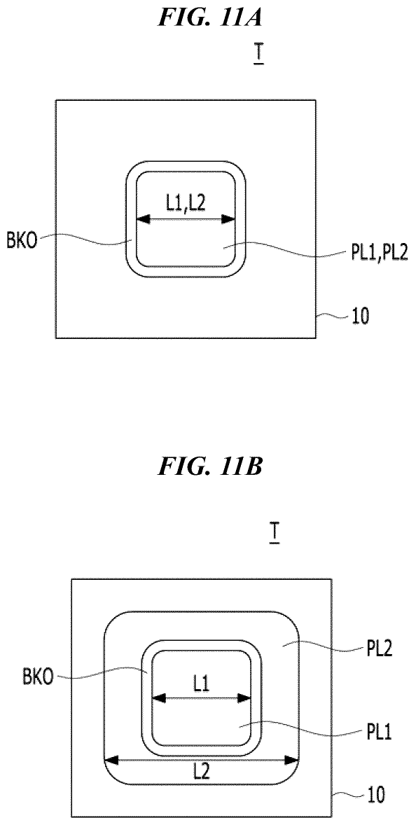

FIGS. 11A, 11B, 11C, and 11D are schematic plan views showing various shapes of the light emitting display device of the present disclosure. FIGS. 11A to 11D shows a bank open area BKO provided in the transmission area T. The bank open area BKO may be an area in which the bank is not formed.

Referring to FIG. 11A, the bank open area BKO may be provided in a portion of the transmission area T as an area corresponding to the transmission area T on the substrate 10. Further, the first pattern defining layer PL1 and the second pattern defining layer PL2 on the substrate 10 may have widths L1 and L2, which are the same, respectively, to have the same area, and may be provided within the bank open area BKO. However, the present disclosure is not limited thereto, the first pattern defining layer PL1 and the second pattern defining layer PL2 on the substrate 10 may have widths L1 and L2, which are different.

Referring to FIG. 11B, the bank open area BKO may be provided in a portion of the transmission area T as an area corresponding to the transmission area T on the substrate 10. Further, the first pattern defining layer PL1 on the substrate 10 may have a first width L1 and be provided within the bank open area BKO, and the second pattern defining layer PL2 may have a second width L2 and be provided to be larger than the bank open area BKO and smaller than the transmission area T.

Referring to FIG. 11C, the bank open area BKO may be provided in a portion of the transmission area T as an area corresponding to the transmission area T on the substrate 10. Further, the first pattern defining layer PL1 on the substrate 10 may have a first width L1 and be provided within the bank open area BKO, and the second pattern defining layer PL2 may have a second width L2 and be provided throughout the entirety of the transmission area T.

Referring to FIG. 11D, the bank open area BKO may be provided throughout the entirety of the transmission area T as an area corresponding to the transmission area T on the substrate 10. Correspondingly, the first pattern defining layer PL1 and the second pattern defining layer PL2 may be provided throughout the entirety of the transmission area T.

As shown in FIG. 9A to FIG. 11D, the light emitting display device of the present disclosure may form the first pattern defining layer PL1 and the second pattern defining layer PL2 having various structures in the transmission area T. Further, the first insulating layer IL1, the second insulating layer IL2, and the bank corresponding to the transmission area T may be selectively removed. In addition, the areas of the bank open area BKO, the first pattern defining layer PL1, and the second pattern defining layer PL2 corresponding to the transmission area T may be varied. Accordingly, the light emitting display device of the present disclosure may improve the transmittance of the transmission area T through the first pattern defining layer PL1 and the second pattern defining layer PL2 provided in the transmission area T, and may maximize the transmittance of the transmission area T by selectively removing the insulating layers IL1, IL2, and bank.

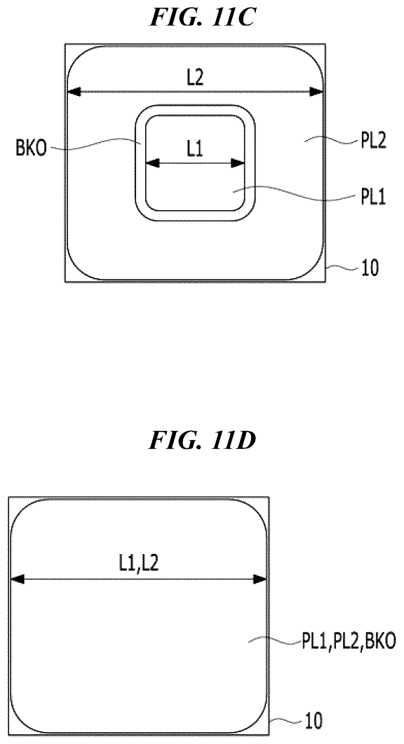

FIG. 12 is a cross-sectional view of a light emitting display device of the present disclosure according to a fourth exemplary embodiment. For example, FIG. 12 may be a cross-sectional view of FIG. 10B or FIG. 11D.

Referring to FIG. 12, the light emitting display device of the present disclosure according to the fourth exemplary embodiment may include a light emitting device 460 including a first electrode 461, an intermediate layer 463, and a second electrode 465 provided in each of a plurality of emission areas EA on the substrate 10, a first capping layer 491 and a second capping layer 492 sequentially provided on the light emitting device 460 and having different refractive indexes, a first pattern defining layer 481 adjacent to the side surface of the second electrode 465 and provided in each of a plurality of transmission areas T on the substrate 10, and a second pattern defining layer 483 adjacent to the side surface of the second capping layer 492 and configured to overlap the first pattern defining layer 481.

In the light emitting display device of the present disclosure according to the fourth exemplary embodiment, a first insulating layer 440, a second insulating layer 450, and a bank 470 may be removed from the transmission area T. That is, in the light emitting display device of the present disclosure according to the fourth exemplary embodiment, the first insulating layer 440, the second insulating layer 450, and the bank 470 may expose the transmission area T. Further, in the light emitting display device of the present disclosure according to the fourth exemplary embodiment, the first pattern defining layer 481 and the second pattern defining layer 483 may be provided throughout the entirety of the transmission area T. Accordingly, a first vertical distance V1 from the upper surface of the substrate 10 to the lower surface of the first pattern defining layer 481 may be shorter than a second vertical distance V2 from the upper surface of the substrate 10 to the lower surface of the second electrode 465. The light emitting display device of the present disclosure according to the fourth exemplary embodiment may maximize transmittance of the transmission area T. Accordingly, as the transmittance of the transmission area T is improved, the light emitting display device of the present disclosure may improve the overall light transmittance of the sensor, thereby being capable of improving perceived image quality.

A light emitting display device according to one exemplary embodiment of the present disclosure will be described as follows.

The light emitting display device according to one exemplary embodiment of the present disclosure may include a light emitting device including a first electrode, an intermediate layer, and a second electrode at each of a plurality of emission areas on a substrate, a first capping layer and a second capping layer sequentially provided on the light emitting device and configured to have different refractive indexes, a first pattern defining layer adjacent to a side surface of the second electrode and provided at each of a plurality of transmission areas on the substrate, and a second pattern defining layer adjacent to a side surface of the second capping layer and configured to at least partially overlap the first pattern defining layer.

In a light emitting display device according to one exemplary embodiment of the present disclosure, the second pattern defining layer may have a lower refractive index than the second capping layer.

In a light emitting display device according to one exemplary embodiment of the present disclosure, a refractive index of the second pattern defining layer may be equal to or higher than a refractive index of the first pattern defining layer.

In a light emitting display device according to one exemplary embodiment of the present disclosure, the first capping layer may have a lower refractive index than the second capping layer.

In a light emitting display device according to one exemplary embodiment of the present disclosure, the first pattern defining layer may have a lower refractive index than the second electrode.

In a light emitting display device according to one exemplary embodiment of the present disclosure, an area of the second pattern defining layer may be same to an area of the first pattern defining layer, and an entire part of the first pattern defining layer overlaps the second pattern defining layer.

In a light emitting display device according to one exemplary embodiment of the present disclosure, the second pattern defining layer may have a larger area than the first pattern defining layer, and an entire part of the first pattern defining layer overlaps the second pattern defining layer.

In a light emitting display device according to one exemplary embodiment of the present disclosure, the first pattern defining layer and the second pattern defining layer may comprise a polycyclic aromatic compound.

In a light emitting display device according to one exemplary embodiment of the present disclosure, the polycyclic aromatic compound includes an organic molecule including a core moiety and at least one terminal moiety bonded to the core moiety.

In a light emitting display device according to one exemplary embodiment of the present disclosure the first capping layer comprises an organic material, and the second capping layer may comprise an inorganic material.

In a light emitting display device according to one exemplary embodiment of the present disclosure, the intermediate layer may comprise a plurality of common layers and an electron injection layer in contact with the second electrode. The electron injection layer and the second electrode may be adjacent to a side surface of the first pattern defining layer.

In a light emitting display device according to one exemplary embodiment of the present disclosure, a thickness of the first pattern defining layer may be smaller than a total thickness of the electron injection layer and the second electrode.

In a light emitting display device according to one exemplary embodiment of the present disclosure, a thickness of the second pattern defining layer may be smaller than a thickness of the second capping layer.

A light emitting display device according to one exemplary embodiment of the present disclosure may further comprise a bank on the substrate to expose each of the plurality of emission areas and the plurality of transmission areas.

In a light emitting display device according to one exemplary embodiment of the present disclosure, a first vertical distance from an upper surface of the substrate to a lower surface of the first pattern defining layer may be shorter than a second vertical distance from the upper surface of the substrate to a lower surface of the second electrode.

A light emitting display device according to one exemplary embodiment of the present disclosure may further comprise at least one transistor between the substrate and the light emitting device and a first insulating layer and a second insulating layer to cover the at least one transistor. At least one of the first insulating layer and the second insulating layer may expose each of the plurality of transmission areas. Or at least one of the first insulating layer and the second insulating layer may be not present at each of the plurality of transmission areas.

A light emitting display device according to one exemplary embodiment of the present disclosure may further comprise at least one transistor between the substrate and the light emitting device; a first insulating layer and a second insulating layer to cover the at least one transistor; and a bank on the second insulating layer, wherein at least one of the first insulating layer, the second insulating layer, and the bank is not present at each of the plurality of transmission areas.

In a light emitting display device according to one exemplary embodiment of the present disclosure, at least a portion of each of the plurality of transmission areas is provided with a bank open area.

In a light emitting display device according to one exemplary embodiment of the present disclosure, a width of the second pattern defining layer is greater than or equal to a width of the bank open area, and less than or equal to a width of the transmission area.

In a light emitting display device according to one exemplary embodiment of the present disclosure, each of a width of the first pattern defining layer and a width of the second pattern defining layer is less than or equal to a width of the bank open area.

In a light emitting display device according to one exemplary embodiment of the present disclosure, a width of the first pattern defining layer is less than a width of the bank open area, and the width of the bank open area is less than a width of the second pattern defining layer.

A manufacturing method of light emitting display device according to one exemplary embodiment of the present disclosure may comprise: forming a light emitting device at each of a plurality of emission areas on a substrate, the light emitting device comprising a first electrode, an intermediate layer, and a second electrode; sequentially forming a first capping layer and a second capping layer provided on the light emitting device, the first capping layer and second capping layer being configured to have different refractive indexes; forming a first pattern defining layer adjacent to a side surface of the second electrode at each of a plurality of transmission areas on the substrate; and forming a second pattern defining layer adjacent to a side surface of the second capping layer, the second pattern defining layer being configured to at least partially overlap the first pattern defining layer.

As is apparent from the above description, a light emitting display device of the present disclosure has the following effects.

First, the light emitting display device of the present disclosure has a first pattern defining layer adjacent to a second electrode and having a higher transmittance than the second electrode and a second pattern defining layer adjacent to a second capping layer and having a higher transmittance than the second capping layer in an area corresponding to each of transmission areas of a sensor, thereby being capable of improving transmittance of the transmission areas. Accordingly, the light emitting display device of the present disclosure improves the overall transmittance of the sensor, thereby having the effect of improving perceived image quality.

Second, in the light emitting display device of the present disclosure, the first pattern defining layer and the second pattern defining layer have low affinities for the second electrode and the second capping layer, respectively, so that the second electrode and the second capping layer may be formed only through the first pattern defining layer and the second pattern defining layer, and thus, a separated mask may not be required. Accordingly, the light emitting display device of the present disclosure has environmental, social, and governance (ESG) effects in terms of environmental friendliness and process optimization.

The present disclosure described as above is not limited by the exemplary embodiments described herein and accompanying drawings, and it should be apparent to those skilled in the art that various substitutions, changes and modifications which are not exemplified herein but are still within the spirit and scope of the present disclosure may be made. Therefore, the scope of the present disclosure is defined not by the detailed description, but by the claims and their equivalents, and all variations within the scope of the claims and their equivalents are to be construed as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a light emitting device comprising a first electrode, an intermediate layer, and a second electrode at each of a plurality of emission areas on a substrate;
a first capping layer and a second capping layer sequentially provided on the light emitting device and configured to have different refractive indexes;
a first pattern defining layer adjacent to a side surface of the second electrode and provided at each of a plurality of transmission areas on the substrate; and
a second pattern defining layer adjacent to a side surface of the second capping layer and configured to at least partially overlap the first pattern defining layer.

2. The light emitting display device according to claim 1, wherein the second pattern defining layer has a lower refractive index than the second capping layer.

3. The light emitting display device according to claim 1, wherein a refractive index of the second pattern defining layer is equal to or higher than a refractive index of the first pattern defining layer.

4. The light emitting display device according to claim 1, wherein the first capping layer has a lower refractive index than the second capping layer.

5. The light emitting display device according to claim 1, wherein the first pattern defining layer has a lower refractive index than the second electrode.

6. The light emitting display device according to claim 1, wherein an area of the second pattern defining layer is same to an area of the first pattern defining layer, and an entire part of the first pattern defining layer overlaps the second pattern defining layer.

7. The light emitting display device according to claim 1, wherein the second pattern defining layer has a larger area than the first pattern defining layer, and an entire part of the first pattern defining layer overlaps the second pattern defining layer.

8. The light emitting display device according to claim 1, wherein each of the first pattern defining layer and the second pattern defining layer comprises a polycyclic aromatic compound.

9. The light emitting display device according to claim 1, wherein the first capping layer comprises an organic material, and the second capping layer comprises an inorganic material.

10. The light emitting display device according to claim 1,
wherein the intermediate layer comprises a plurality of common layers and an electron injection layer in contact with the second electrode, and
wherein the electron injection layer and the second electrode are adjacent to a side surface of the first pattern defining layer.

11. The light emitting display device according to claim 10, wherein a thickness of the first pattern defining layer is smaller than a total thickness of the electron injection layer and the second electrode.

12. The light emitting display device according to claim 1, wherein a thickness of the second pattern defining layer is smaller than a thickness of the second capping layer.

13. The light emitting display device according to claim 1, further comprising a bank on the substrate to expose each of the plurality of emission areas and the plurality of transmission areas.

14. The light emitting display device according to claim 1, wherein a first vertical distance from an upper surface of the substrate to a lower surface of the first pattern defining layer is shorter than a second vertical distance from the upper surface of the substrate to a lower surface of the second electrode.

15. The light emitting display device according to claim 1, further comprising:
at least one transistor between the substrate and the light emitting device; and
a first insulating layer and a second insulating layer to cover the at least one transistor,
wherein at least one of the first insulating layer and the second insulating layer is not present at each of the plurality of transmission areas.

16. The light emitting display device according to claim 1, further comprising:
at least one transistor between the substrate and the light emitting device;
a first insulating layer and a second insulating layer to cover the at least one transistor; and
a bank on the second insulating layer,
wherein at least one of the first insulating layer, the second insulating layer, and the bank is not present at each of the plurality of transmission areas.

17. A light emitting display device comprising:
a plurality of first electrodes at each of a plurality of emission area on a substrate;
an intermediate layer on the plurality of first electrodes;
a first pattern defining layer at each of a plurality of transmission areas on the substrate;
a cathode adjacent to a side surface of the first pattern defining layer, the cathode non-overlapping the first patterning layer;
a first capping layer on the cathode;
a second pattern defining layer to overlap the first pattern defining layer; and
a second capping layer adjacent to a side surface of the first pattern defining layer, the second capping layer non-overlapping the second patterning layer.

18. The light emitting display device according to claim 17, wherein the first capping layer and the second capping layer have different refractive indices.

19. The light emitting display device according to claim 17, wherein a refractive index of the second pattern defining layer is equal to or higher than a refractive index of the first pattern defining layer.

20. The light emitting display device according to claim 17, wherein the second pattern defining layer has a larger area than the first pattern defining layer, and an entire part of the first pattern defining layer overlaps the second pattern defining layer.
